(19) United States
(12) Patent Application Publication
(10) Pub. No.: US 2024/0068129 A1
(43) Pub. Date: Feb. 29, 2024

(54) DEVICE FOR GROWING AN ARTIFICIALLY PRODUCED SINGLE CRYSTAL, IN PARTICULAR A SAPPHIRE SINGLE CRYSTAL

(71) Applicant: FAMETEC GmbH, Leonding (AT)

(72) Inventors: Robert EBNER, Leonding (AT); Jong Kwan PARK, Leonding (AT); Gourav SEN, Leonding (AT); Ghassan BARBAR, Neunkirchen (DE)

(73) Assignee: FAMETEC GmbH, Leonding (AT)

(21) Appl. No.: 18/270,076

(22) PCT Filed: Dec. 28, 2021
(86) PCT No.: PCT/AT2021/060487

§ 371 Date: Jun. 28, 2023

(30) Foreign Application Priority Data
Dec. 29, 2020 (AT) A 51144/2020

(51) Int. Cl. C30B 35/00; C30B 29/20

(52) U.S. Cl. CPC C30B 35/002; C30B 29/20

(57) ABSTRACT

A device for growing at least one artificially manufactured single crystal, in particular a sapphire single crystal, includes at least one crucible wall, the crucible wall having an open first end portion and a base-side second end portion arranged at a distance from the first end portion along a longitudinal axis, wherein when viewed from the at least one crucible wall in cross-section in relation to the longitudinal axis a crucible wall inner surface is defined, and at a distance of one wall thickness thereto a crucible wall outer surface is also defined, at least one crucible base, the crucible base being arranged in the base-side second end portion, and wherein a receiving area for the formation of the single crystal is defined by the crucible wall and the crucible base, wherein the crucible wall has constant thermal conductivity and/or identical mechanical properties across its entire extension.

### CROSS REFERENCE TO RELATED APPLICATIONS

This application is the National Stage of PCT/AT2021/060487 filed on Dec. 28, 2021, which claims priority under 35 U.S.C. § 119 of Austrian Application No. A 51144/2020 filed on Dec. 29, 2020, the disclosure of which is incorporated by reference. The international application under PCT article 21(2) was not published in English.

### BACKGROUND OF THE INVENTION

### 1. Field of the Invention

The invention relates to a device for growing one or more artificially manufactured single crystals in a chamber, in particular a sapphire single crystal,
one or more thin-walled crucibles as described in WO201567552A1, for example, each with a crucible wall, said crucible wall having an open first end portion and a second base-side end portion arranged at a distance thereto in the direction of a longitudinal axis, wherein a crucible wall inner surface and a crucible wall outer surface distanced thereto in a crucible wall thickness are defined viewed in cross section in relation to the longitudinal axis.
each crucible base, said crucible base being arranged in the second end portion, and
wherein the crucible wall and the crucible base define a receiving area for forming the single crystal.

### 2. Description of the Related Art

A device of the type mentioned at the beginning is known from JP H01145392 A. Other relevant devices are described in WO2014/148156 A1, CN 203393259 U and US2011/253033 A1.

Manufacturing large single crystals, such as those used in the production of wafers, is known from the prior art, for example from KR 10 2017-0026734 A. Manufacturing large single crystals, such as those used in the production of wafers, is known from the prior art, for example from KR 10 2017-0026734 A. As is known, the quality requirements of these crystals is very high, meaning that a wide variety of methods and devices for manufacturing these are described in the prior art. One method type envisages providing and melting the “raw material” in a crucible. The single crystal is then created in the crucible itself by way of controlled cooling of the melt. The devices used for this are configured in a great variety of ways. US 2013/152851 A1 describes a device for producing an Si single crystal having an isolation chamber, in which the crucible/crucibles and heating elements are arranged next to and above the crucible/crucibles, for example. A reflector is further arranged between the upper heating element and the crucible/crucibles in order to reflect the heat energy radiated from the crucible/crucibles back to into the crucible/crucibles and therefore improve the energy efficiency in growing the single crystal.

WO 2015 067552 A1 describes a device for producing one or more sapphire single crystals comprising a chamber, a crucible/crucibles arranged therein, in which the alumina melt is contained, a heater arranged outside of the crucible to heat the crucible/crucibles and a heat supply unit arranged above a growing single crystal in the crucible to provide heat to the single crystal. This device also provides a reflector, which reflects the heat generated in the chamber to a surface of the single crystal. A disadvantage of conventional solutions is that, in the region of weld seams extending along the height of the crucible wall, imperfections form in the crystal during crystal growth, which must be removed after an ingot has been finished by grinding the same.

### SUMMARY OF THE INVENTION

The problem of the present invention was to create a single crystal of very high quality, to increase yield and, overall, to reduce the energy consumption per single crystal produced.

This problem is solved by a device of the type mentioned at the beginning in that the at least one crucible has constant thermal conductivity and/or identical mechanical properties over its entire extension.

The solution according to the invention can prevent faults from forming in the single crystal during crystal growth along a discontinuity in the crucible wall, such as a weld seam, for example. This leads to a larger yield in relation to the cross-sectional area of an ingot, because fewer to absolutely no ingot portions with defects need be removed as is necessary for conventional solutions, and larger wafers are obtained. This therefore also reduces the energy requirements in relation to the surface of the wafers cut from the surface of the ingot/ingots. Several crystals can be grown simultaneously in an oven by arranging several crucibles in the oven using the solution in accordance with the invention.

According to a preferred variant of the invention, the crucible wall inner surface has a similar surface formation across its entire surface. This variant facilitates faultless crystal growth, also viewed in the radial direction, of the near-surface portions of the crystal.

According to a further advantageous embodiment of the invention, the crucible wall can be provided closed on itself in an annular and seamless configuration. By dispensing with a weld seam, a crucible wall free of discontinuities can be achieved, which facilitates crystal growth free of defect points.

An advancement of the invention is that the crucible wall has a similar structural composition across its entire extension.

In accordance with a particularly preferred embodiment, the crucible wall can be made from iridium (Ir), tungsten (W) or molybdenum (Mo).

For the production of a particularly homogeneous crucible wall, it has proven advantageous for the crucible wall to be manufactured using a centrifugal casting method.

The energy efficiency of the process can be improved by the crucible being open at the top and at least one upper heating element being arranged above the crucible, wherein a thermal diffuser element for generating even heat distribution is arranged between the upper heating element and the crucible. This variant enables direct heating of the interior of the crucible, such that particularly effective heat influx into the melt or base material is enabled.

Particularly high quality crystals can be obtained by aligning a crystallographic c-axis of the seed crystal in accordance with a longitudinal axis of the crucible extending upwardly along the crucible wall.

The quality of the crystal can be further optimized in that the seed crystal is substantially disc shaped,
having a first flat side and a second flat side;
having a longitudinal center axis, said longitudinal center axis extending from the first flat side to the second flat side, wherein the c-axis of the seed crystal is coincidental with the longitudinal center axis of the seed crystal.

### BRIEF DESCRIPTION OF THE DRAWINGS

To improve understanding of the invention, it is described in more detail in the following figures.

These show in significantly simplified, schematic representation:

FIG. 1 a first possible embodiment of a device for growing an artificially manufactured sapphire crystal, in a sectional view;

FIG. 2 a second possible embodiment of a device for growing an artificially manufactured sapphire crystal, in a sectional view;

FIG. 3 a third embodiment of a device for growing an artificially manufactured sapphire crystal, in a sectional view.

### DETAILED DESCRIPTION OF PREFERRED EMBODIMENTS

It is worth noting here that the same parts have been given the same reference numerals or same component configurations in the embodiments described differently, yet the disclosures contained throughout the entire description can be applied analogously to the same parts with the same reference numerals or the same component configurations. The indications of position selected in the description, such as above, below, on the side etc. refer to the figure directly described and shown, and these indications of position can be applied in the same way to the new position should the position change.

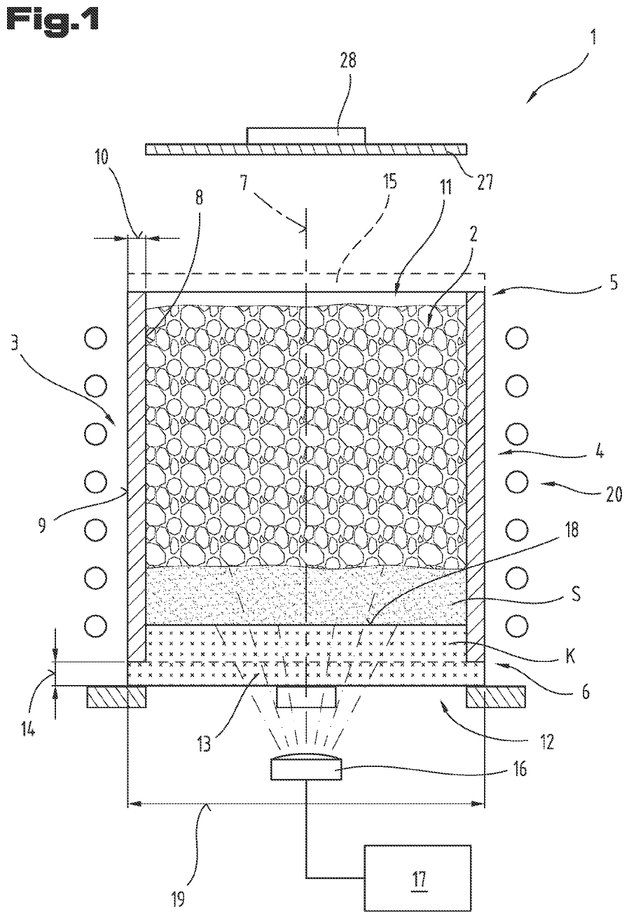

FIG. 1 shows a first embodiment of device 1, which serves to or is configured to grow a crystal, in particular an artificially manufactured sapphire crystal. The chemical formula for sapphire is Al₂O₃ and it occurs naturally, and is used as a gemstone or similar.

Synthetic or artificial manufacturing is performed starting with what is known as the base material 2, which can have a lumpy, grainy, or even powdery structure. Larger pieces can also be used to achieve better bulk density. The base material 2 is placed into a receiving device or receiving container, generally referred to as the crucible 3, where it is melted using heat application as is known in the art.

The melt, hereinafter referred to as “S”, is cooled down, leading to the solidifying and formation of crystal “K”. Such a crystal “K” is preferably a single crystal form of aluminium oxide (Al₂O₃. The synthetically manufactured sapphire crystal “K” has a hardness of 9 on the Mohs scale. Furthermore, products made from it such as wafers, watch faces, housings, LEDs or similar, have high scratch resistance. “K” crystals with crystal clear properties or depending on additives with a colored appearance are preferably formed.

Device 1 comprises a crucible wall 4, said wall having a first end portion 5 and a second end portion 6 arranged at a distance from the first wall. A longitudinal axis 7 extends between the two end portions 5 and 6. The crucible 3 is arranged in a kiln and can be heated using heating elements. For the sake of completeness, it should be noted here that device 1 comprises further elements, such as a control/regulation unit, etc. However, because they can be in accordance with the prior art, this description refers to the relevant prior art instead of going into further detail.

The first end portion 5 of the crucible 3 has an open configuration in this embodiment 5 When longitudinal axis 7 is aligned perpendicularly, the second end portion 6 forms the base-side end portion and has an entirely or predominantly open configuration. The crucible wall 4 is fundamentally tubular and can have a large variety of cross-sectional shapes in relation to the longitudinal axis 7. The cross-sectional shape depends on the cross-section of the crystal “K” to be manufactured. For example, the inner cross section can be round, oval, or polygonal. The polygonal cross section can, for example, be formed by a square, a rectangle, a pentagon, a hexagon, an octagon or the like.

Crucible wall 4 defines a crucible wall inner surface 8 and a crucible wall outer surface 9, wherein when viewed in a radial direction the two crucible wall surfaces 8 and 9 form a crucible wall thickness 10.

To form a receiving area 11, the crucible wall 4 has a closed configuration with a crucible base 12 on the base side of its second end portion 6. The crucible wall 4 and the crucible base 12 thereby define the receiving area 11.

In this embodiment and the embodiments described hereinafter, it is provided for that the crucible base 12 itself is or shall be formed predominantly exclusively from a plate 13 made from a previously artificially manufactured sapphire crystal “K”. It is preferred, however, that the entire crucible base 12 is exclusively formed from plate 13, itself made from the previously artificially manufactured sapphire crystal “K”. The plate 13 which forms the crucible base 12 thereby forms a seed crystal for the sapphire crystal “K” to be manufactured. The dividing line between the plate 13 and the already newly manufactured sapphire crystal “K” was depicted respectively with a dashed line, because at the beginning of the melting process of the base material 2 and the formation of melt “S”, the surface of the plate 13 which is facing the receiving area 11 is at least partially or entirely melted and with progressing cooling and crystallization, a conglomerate monolithic sapphire crystal “K” is formed.

The plate 13 that forms the crucible base 12 can have a plate thickness of at least 1 mm and up to several mm 14, derived from a plate thickness value range with a lower limit of 0.5 mm, in particular 1 mm, and an upper limit of 5 mm, in particular 2 mm.

Furthermore, the open end portion 5 of the crucible wall 4 with a wall thickness of 0.5 mm to several mm can be covered by a crucible lid 15. A material from the group containing iridium (Ir), tungsten (W), and molybdenum (Mo) can be used a possible material for forming the crucible wall 4 and/or crucible lid 15.

Since the sapphire crystal “K” as well as the plate 13 that forms the crucible base 12 usually are or become crystal clear or transparent, it is possible to carry out a variety of measurements in receiving area 11 through plate 13. To do so, at least one sensor 16 shall be provided depending on the measurement to be carried out. The at least one sensor 16 is arranged on the side of plate 13 that forms crucible base 12 that is not facing receiving area 11 and is represented in a simplified manner. The sensor 16 can have a communication link with a control device 17 and transmit the measurement value(s) obtained to said control device.

The sensor 16 can, for example, be configured to determine the relative position of a boundary layer 18 between the solidified sapphire crystal “K” and melt “S”, which is still located above and is made from the base material. The measurement signals emitted by sensor 16 are indicated/represented by dashed lines up to the boundary layer 18. It would, however, also be possible to determine the position of the melt surface within the receiving area 11 using said sensor 16 and/or a further sensor not depicted here. In this embodiment and the embodiments described hereinafter, the measuring signals that end at the melt surface are indicated by dashed and dotted lines. It would, however, also be possible to detect the respective position or height location using the same sensor 16 and the determined different path duration of the measuring signals to the boundary layer 18 between the solidified sapphire crystal “K” and the melt “S” which is still located above, or up to the melt surface.

The sensor 16, which can also be designated as a detector, probe, measuring probe, or transducer, is a technical component that can detect certain physical or chemical properties and/or the material composition of its surroundings, either qualitatively or as a quantitative parameter. These values are detected using physical, chemical, or biological effects and converted into an electrical signal that can be processed further and where necessary transmitted to the control device 17. The device 1 and the process flow can be regulated and controlled using the control device 17. The sensor 16 can, for example, have a device for generating a laser beam (e.g. a laser diode) or a device for detecting a reflected laser beam, for example a photo diode, in particular an Avalanche Photo Diode (APD) or a CCD chip. Furthermore, the sensor 16 can comprise further electronic elements such as a signal amplifier or a microphone/signal processor. A travel time measurement by laser can, for example, determine the current position of the boundary layer between the melt and the crystal.

It is further shown that when the longitudinal axis 7 of the crucible wall 4 is aligned perpendicularly, it can be supported on its base-side second end portion 6, namely its base-side crucible front surface, on the plate 13 that forms the crucible base 12 formed from the previously artificially manufactured sapphire crystal “K”. The external dimension of the plate 13 shall therefore be formed larger than the thin internal dimension of the crucible wall inner surface. Thus, the plate 13 that forms the crucible base 12 can, for example, have an external dimension 19 that corresponds to a cross-sectional dimension as defined by the crucible wall outer surface 9. A radial protrusion of the plate beyond the external dimension of the crucible wall 4 can thereby be prevented. To enable demolding and possible support of the crucible wall 4 in its base-side second end portion 6, as represented by dashed lines, the external dimension 19 of the plate 13 can be selected as smaller than the external cross-sectional dimension defined by the crucible wall external dimension 9.

Furthermore, using the plate 13, the crucible wall 4 can be supported on a supporting device that is not specified in more detail here. In this embodiment, the support device is formed by separate support elements, preferably arranged across the circumference. A simplified schematic diagram indicates a heating device 20 outside the crucible wall 4, said heating device being usable to melt the base material 2 as placed in the receiving area 1I to a melt bath, said melt “S” crystallizing and solidifying to form sapphire crystal “K” when it cools.

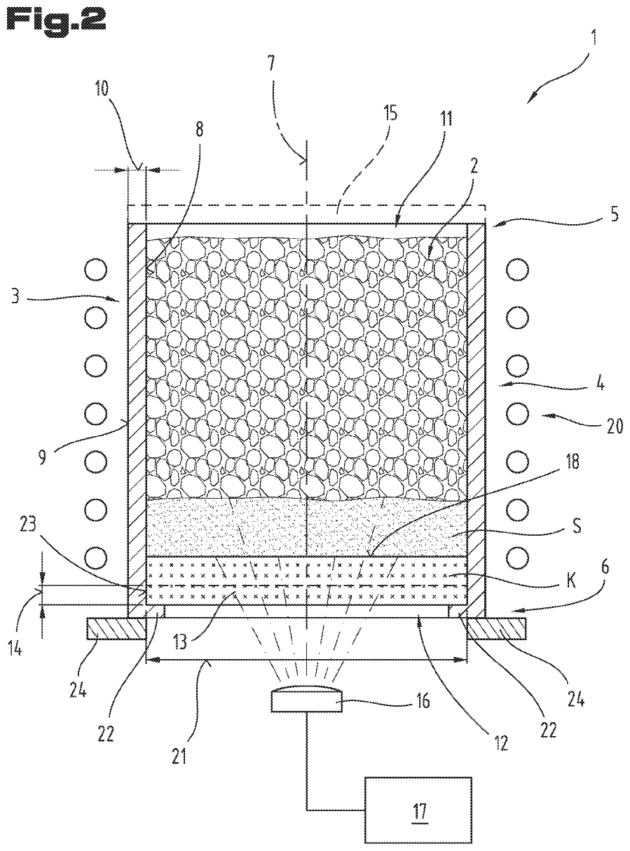

FIG. 2 shows a further, optionally independent, embodiment of device 1, wherein again the same reference numerals or component designations as in the preceding FIG. 1 are used for identical parts. To avoid unnecessary repetitions, reference is made to the detailed description in preceding FIG. 1.

The device 1 itself comprises the crucible wall 4, the crucible lid 15 where required and the crucible base 12 formed of the crystalline plate 13.

The plate 13 that forms the crucible base 12 has a maximum external dimension 19 here that corresponds to a cross-sectional dimension defined by the crucible wall inner surface 8. Furthermore, the plate 13 is inserted into the base area of receiving area 11.

In order to achieve positioned holding of the plate 13 relative to the crucible wall 4, several support extensions 22 can be provided for. The support extensions 22 protrude over the crucible wall inner surface 8 in the direction of the longitudinal axis 7 and are preferably arranged across the circumference of the crucible wall inner surface 7. Furthermore, the support extensions 22 can form an integral part of the crucible wall 4 and can be made from the same material as the crucible wall 4. The term integral is understood here as meaning that the support extensions 22 form one piece together with the crucible wall 4.

If the support extensions 22 are provided, the plate 13 forming the crucible base 12 is supported on the support extensions 22 on the side facing the respective open first end portion 5. The support extensions 22 are usually arranged as protrusions or projections. It would, however, also be possible to form the support extensions 22 from a support flange running along the inner circumference.

The outer dimension 19 of the plate 13 that forms the crucible base 12 can be selected such that it constantly forms a seal on the inner surface of the crucible wall 8 with its outer circumferential front surface 23. The plate 13 shall form a fluid seal on the inner surface of the crucible wall 8.

Again here the previously described sensor 16 can be provided. As the plate 13 is preferably completely inserted into the receiving area 11, the carrying support of the crucible wall 4 with its base-side second end portion 6 can be supported by at least one supporting element 24.

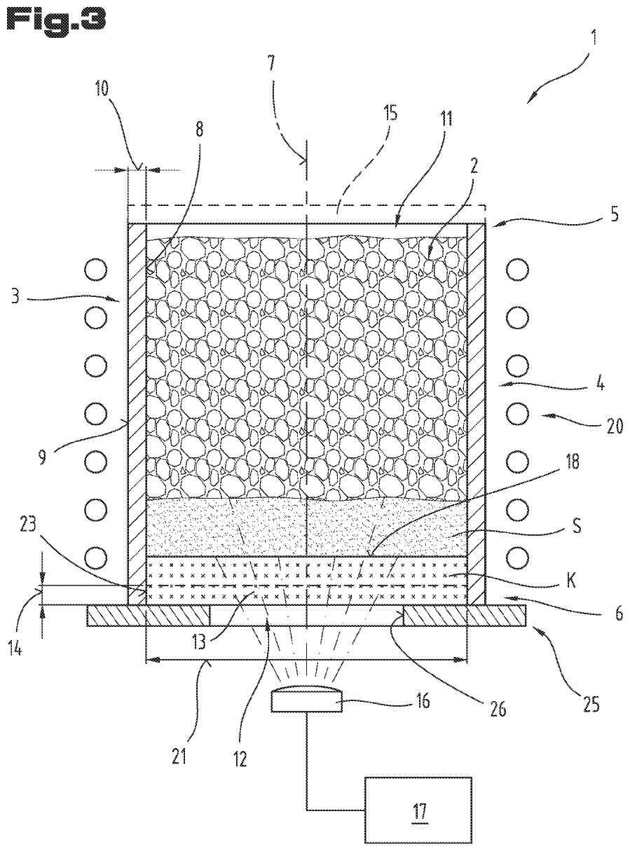

FIG. 3 shows a further and potentially independent embodiment of the device 1, wherein the same reference numerals or component designations as in the previous FIGS. 1 and 2 are used for the same parts. To avoid unnecessary repetition, reference is made to the previous FIGS. 1 and 2.

Device 1 itself comprises the crucible wall 4, the crucible lid 15 where required and the crucible base 12 formed of the crystalline plate 13.

The plate 13 that forms the crucible base 12 again here has a maximum external dimension 19 corresponding to a cross-sectional dimension as defined by the inner surface of the crucible wall 8. Furthermore, the plate 13 is inserted base-side first into the receiving area 11. The outer dimension 19 of the plate 13 that forms the crucible base 12 can be selected such that its outer circumferential front surface 23 is constantly in contact and forms a seal with the inner crucible wall surface 8. The plate 13 shall form a fluid seal on the inner surface of the crucible wall 8. Contrary to the previously described embodiment in FIG. 2, no support extensions 22 are provided for the positioning of plate 13 on the crucible wall 4. It is intended that the crucible wall 4 and the plate 13 that forms the crucible base 12 are jointly placed on a component of device 1 generally designated as a support device 25.

The support device 25 can be formed of individual supporting elements or by a single support plate. Depending on the configuration of the support device 25, it shall have at least one interspersion 26 that passes through the support device 25 in the direction of the longitudinal axis 7. The at least one interspersion 26 serves to allow viewing of the receiving area 11 of the previously described sensor 16. The determination or various determinations can thereby be performed with the sensors 16 provided for that purpose.

Thereby not only the relative position of the previously described boundary layer 18 between the already formed sapphire crystal “K” and the melt “S” can be determined, but also or additionally the quality and/or purity of the already formed sapphire crystal “K”. Should, for example, false crystallization and/or a quality deviation be identified, the further crystallization process and the melting of the base material 2 can be terminated, such that a high proportion of energy costs can be saved.

Due to the predominantly not closed and therefore also open configuration of the crucible wall 4 in the base-side end portion 6, the finished, crystallized sapphire crystal “K” can either be removed through the open, base-side second end portion 6, as shown and described in FIGS. 1 and 3, or by applying a base-side pressure force (demolding force) to the finished, crystallized sapphire crystal “K” in the direction of the open first end portion 5 and thereby be demolded from the crucible wall 4.

The method for growing the artificially manufactured sapphire crystal “K” can preferably be performed by using or applying device 1 with the crucible wall 4 and the plate 13 that forms the crucible base 12 made from the crystalline material as a seed crystal. As an alternative to the crucibles shown in FIGS. 1 and 3, a crucible with a closed base can be used, wherein the seed crystal or the plate 13 is then inserted into the crucible.

At least the following steps for performing the method are provided for:

Arrangement of a monocrystalline seed crystal made from sapphire in a base area of the crucible 3 and alignment of a crystallographic c-axis of the seed crystal or the plate 13 with a longitudinal axis 7 of the crucible which extends up the crucible wall 4. The crystallographic c-axis is hereby understood as the crystal's optical axis along which each polarization component of a light beam is subject to the same refractive index. Arrangement of the base material 2, in particular Al₂O₃, in the crucible 3 on the seed crystal and melting of the base material 2, wherein crystal growth through crystallization on a boundary layer between the melted base material 2 and the seed crystal occurs progressively along the c-axis. The seed crystal is preferably arranged such that its c-axis is arranged coincidentally with the crucible's longitudinal axis.

The seed crystal is substantially disc-shaped, wherein the seed crystal's c-axis is coincidental with the seed crystal's longitudinal center axis. Preferably, the seed crystal shall have a curvature having a highest and a lowest point in relation to the longitudinal center axis, wherein a distance between the highest point and the lowest point of the curvature to the longitudinal center axis is smaller than 7 μm. The curvature of the seed crystal can be concave or convex. The curvature hereby relates to the curvature of a seed crystal, i.e. following one-sided or both-sided polishing of the seed crystal. The position of the c-axis can be marked on the seed crystal, in particular on the side not facing the direction of crystal growth, for example with a dot or notch. The position of the c-axis can also be marked accordingly on the surface of the finished ingot that is opposite the seed crystal. Furthermore, the positions of the wafers on the finished ingot can be marked so as to simplify cutting the wafers out of the ingot.

It should be pointed out here that several crystals can be grown at the same time in one kiln by arranging several crucibles 3 in the kiln. If several crystals are grown simultaneously in one kiln, the method described herein is performed for each crystal. Simultaneously growing several crystals in one kiln is particularly advantageous regarding energy requirements.

The crucible 3 or several crucibles 3 is/are arranged in one kiln. At least one heating element is arranged in the kiln. The at least one heating element serves to melt the crucible contents, as is known in the art. In particular, at least one heating element is arranged above the crucible 3 or the plurality of crucibles. However, further heating elements can also be provided for that are arranged to the side of the crucible wall 4 or the crucible walls 4. Several heating elements can be arranged along the circumference of the crucible 3 or crucibles 3. The heating elements can be configured in accordance with the prior art, for example as resistance heating elements or induction heating elements.

Before heating and melting the base material 2, the kiln or the chamber of the kiln in which the crucible(s) are located can be purged using gas. Thereafter, the gas can be pumped out and a process pressure set. Before the process is started and the base material 2 is melted by heating, the moisture content of the pumped out gas can be measured. The heating and melting of the raw material only occurs when the moisture content is below the threshold limit. The moisture content of the pumped out gas can be measured using a mass spectrometer, for example. Capacitive methods can be used as an alternative or in addition.

During the process, beginning with the step of growing a crystal between a melt surface, in particular a Al₂O₃-melt surface and the boundary surface of the growing single crystal, in particular the sapphire single crystal to the Al₂O₃ melt, a temperature difference of ΔT can be kept constant at least for the majority of the duration of crystal growth.

Because the crucible 3 or the crucibles 3 is or are open at the top when viewed from the seed crystal, if the lid 15 is removed, a transom of base material melt can be heated from above by at least one heating element as depicted in FIG. 1 with reference numeral 28 when the crucible/crucibles 3 is/are not covered, wherein the heating element is arranged over an open side of the crucible/crucibles 3, and wherein preferably a heat diffuser element 27, for example a diffuser plate, can be arranged between the heating element 28 and the open, upper side of the crucible/crucibles 3 to generate even heat distribution directly at heating element 28. The diffuser plate can preferably be made from graphite.

Furthermore, the crucible wall 4 of the crucible/crucibles 3 can have a constant thermal conductivity and/or the same optical and/or the same mechanical properties along its entire extension. The crucible wall 4 can also have an identical surface finish on its crucible inner wall 8. Furthermore, the cylindrical crucible wall 4 can be annularly closed on itself and seamless, and have an identical structural construction along its entire extension. The crucible wall 4 thereby preferably has no vertically extending welding or joining spots.

The seamless and homogeneous construction of the crucible wall 4 avoids local weakening of the material as is the case with a weld seam. In particular, flaws in the single crystal that form along the weld seam during crystal growth can be prevented. A centrifugal casting method is particularly suitable for forming the crucible wall 4. The crucible wall 4 can then later be fused with the crucible base 12. Where the crucible base 12 is formed by the seed crystal itself, the crucible wall 4 can be placed on the crucible base. Where the crucible base 12 is formed from the same or a similar material as the crucible wall 4, the crucible wall 4 can be fused with the crucible base 12, for example by welding. In this case, the seed crystal can be inserted into the crucible 4.

The single crystal to be manufactured preferably has an outer diameter/cross-sectional surface which corresponds to the inner diameter/interior geometry of the crucible 3. The resulting single crystal thereby preferably completely fills the cross-sectional surface of the crucible 3. The single crystal is therefore preferably not removed from the crucible. For example, the finished single crystal can have a diameter of between 5 cm and 50 cm and a height of between 5 cm and 80 cm. It should, however, be pointed out that these values are illustrative and are not to be understood as limiting the scope of protection.

By cutting transversely to the longitudinal axis 7, the obtained single crystal ingot can be cut into wafers that are substantially disc-shaped—having a first flat side and a second flat side; having a longitudinal center axis, said longitudinal center axis extending from the first flat side to the second flat side, wherein at least one flat side has a curvature; said curvature having a highest point and a lowest point in relation to the longitudinal center axis; wherein a distance between the highest point and the lowest point of the curvature in relation to the longitudinal center axis of the substrate is less than 7 μm after grinding and polishing.

The longitudinal center axis of the wafer is also formed by the c-axis. The curvature of the wafer can be concave or convex.

Using the previously described sensor 16, optionally in combination with the control device 17, the sensor 16 can determine, e.g., the relative position of the boundary layer 18 between the already solidified sapphire crystal “K” and the melt “S”, through plate 13 that forms crucible base 12.

This is possible because the crystal plate that forms the seed crystal is at least transparent or translucent, or even crystal clear. A passage for measuring beams emitted by the sensor 16 through the plate 13 is therefore allowed for.

All value ranges specified in the current description are to be understood such that they include any and all sub-ranges, e.g., the specification 1 to 10 is to be understood such that all sub-ranges, starting from the lower limit 1 and the upper limit 10 are included, i.e., all sub-ranges begin with a lower limit of 1 or more and end at an upper limit of 10 or less, e.g., 1 to 1.7, or 3.2 to 8.1, or 5.5 to 10.

As a matter of form and by way of conclusion, it is noted that, to improve understanding of the structure, elements have partially not been shown to scale and/or enlarged and/or shrunk.

### LIST OF REFERENCE NUMERALS

1 Device
2 Base material
3 Crucible
4 Crucible wall
5 First end portion
6 Second end portion
7 Longitudinal axis
8 Crucible wall inner surface
9 Crucible wall outer surface
10 Crucible wall thickness
11 Receiving area
12 Crucible base
13 Plate
14 Plate thickness
15 Crucible lid
16 Sensor
17 Control device
18 Boundary layer
19 External dimension
20 Heating device
21 External dimension
22 Support extensions
23 Circumferential front surface
24 Support element
25 Support device
26 Interspersion
27 Heat diffuser element
28 Heating element

1: A device (1) for growing at least one artificially manufactured sapphire single crystal, comprising
at least one crucible wall (4), said crucible wall having an open first end portion (5) and a base-side second end portion (6) arranged at a distance from the first end portion along a longitudinal axis (7), wherein when viewed from the at least one crucible wall (4) in cross-section in relation to the longitudinal axis (7) a crucible wall inner surface (8) is defined, and at a distance of one wall thickness (10) thereto a crucible wall outer surface (9) is also defined,
at least one crucible base (12), said crucible base (12) being arranged in the base-side second end portion (6), and
wherein a receiving area (11) for the formation of the single crystal is defined by the at least one crucible wall (4) and the at least one crucible base (12),
wherein the at least one crucible wall (4) has constant thermal conductivity and/or identical mechanical properties over its entire extension, wherein the crucible base (12) is formed exclusively from a plate (13) made from a previously manufactured sapphire crystal serving as a seed crystal, wherein an external dimension (19) of the plate (13) that forms the crucible base (12) is selected such that an outer circumferential front surface (23) is constantly in contact and forms a seal with the inner crucible wall surface (8).

2: The device according to claim 1, wherein the crucible wall inner surface (8) has a similar surface configuration across its entire surface.

3: The device according to claim 1, wherein the crucible wall (4) is closed on itself in an annular and seamless configuration.

4: The device according to claim 1, wherein the crucible wall (4) has a similar structural composition across its entire extension.

5: The device according to claim 1, wherein the crucible wall (4) is made from iridium (Ir), tungsten (W) or molybdenum (Mo).

6: The device according to claim 1, wherein the crucible wall (4) is produced using a centrifugal casting method.

7: The device according to claim 1, wherein the crucible (3) is open upwardly and at least one upper heating element (28) is arranged above the crucible (3), wherein a thermal diffuser element (27) for ensuring even heat distribution is arranged between the upper heating element and the crucible (3).

8: The device according to claim 1, wherein a crystallographic c-axis of the seed crystal is aligned in accordance with a longitudinal axis (7) of the crucible (3) extending up the crucible wall.

9: The device according to claim 8, wherein the c-axis of the seed crystal is coincidental with the longitudinal axis (7) of the crucible (3).

10: The device according to claim 1, wherein the seed crystal is substantially disc-shaped,
having a longitudinal center axis, wherein the c-axis of the seed crystal is coincidental with the longitudinal center axis of the seed crystal.
